(19) United States
(12) Patent Application Publication
(10) Pub. No.: US 2003/0132507 A1
(43) Pub. Date: Jul. 17, 2003

(54) Film-integrated key top

(76) Inventor: Miho Odaira, Tokyo (JP)

Correspondence Address: Y. ROCKY TSAO, Fish & Richardson P.C., 225 Franklin Street, Boston, MA, 02110-2804, US

(21) Appl. No.: 10/325,229

(22) Filed: Dec. 18, 2002

(30) Foreign Application Priority Data
Dec. 18, 2001 (JP) 2001-385203

(51) Int. Cl. H01L 23/544

(52) U.S. Cl. 257/620

(57) ABSTRACT

A film-integrated key top include a resin key top and a resin film which is integrated with the resin key top. The resin film may be three types: (1) a matte film that contains powders fine enough to provide the film with translucency, (2) a laminate film that includes a base film and a resin matte layer which is laminated on at least one side of the base film, wherein the resin matte layer contains powders fine enough to provide the film with translucency, (3) a processed film that includes the base film or the laminate film, wherein at least a surface of the film is processed to have a roughened portion. Thus, a film-integrated key top which shows excellent translucency as well as excellent matte texture is provided.

### BACKGROUND OF THE INVENTION

The present invention relates to a key top of the push button which is used in a mobile device or communication device such as a cellular phone. More specifically, the present invention relates to a film-integrated key top which has a resin film integrated with the surface of the resin key top and which shows excellent translucency and matte texture.

For a key top of the push button in a hand-held device, key tops in which a resin film is integrated with the surface of thermoplastic resin key top are known, as disclosed in Japanese Laid-Open Patent Publication No. 54-154461 and Japanese Examined Patent Publication No. 7-54656. The film-integrated key tops of this kind are widely known for their thin body and lightweight.

Japanese Laid-Open Patent Publication No.2000-182470 discloses a key top in which a matte coat of paint containing resin beads is applied to the key top surface such that the beads form irregularities on the surface.

With recent improvement in quality of hand-held devices and increase in design variations, a texture of the key top surface that matches with the design of the surface of the housing to which the key top is attached is desired. However, when the key top which is made of general lustered resin film such as general PET film, to achieve such texture is sometimes difficult.

For example, as disclosed in Japanese Laid-Open Patent Publication No. 54-154461, when the film-integrated key top with a lustered resin film is attached to the housing that has a matte texture, it appears odd due to the different luster against light. In the device which is illuminated with a backlight, as disclosed in Japanese Examined Patent Publication No. 7-54656, uniform translucency of the key top is required.

In Japanese Laid-Open Patent Publication No. 2000-182470, relatively large beads are used to make the key top surface irregular. Thus, the surface tends to become uneven after coating, frequently resulting in wide variations of translucency and matte texture between the products.

The objective of the present invention is to provide a film-integrated key top which shows excellent translucency and matte texture.

### BRIEF SUMMARY OF THE INVENTION

In one aspect of the present invention, a film-integrated key top includes a resin key top and a resin film integrated with the resin key top. The resin film includes a matte film that contains powders fine enough to provide the film with translucency.

In another aspect, a film-integrated key top includes a resin key top and a resin film integrated with the resin key top. The resin film include a laminate film. The laminate film includes a base film and a resin matte layer which is laminated on at least one side of the base film. The resin matte layer contains powders fine enough to provide the layer with translucency.

In yet another aspect, a film-integrated key top includes a resin key top and a resin film integrated with the resin key top. The resin film includes a base film which has translucency. At least a surface of the base film is processed to have a roughened portion.

In still another aspect, a film-integrated key top includes a resin key top and a resin film integrated with the resin key top. The resin film includes a laminate film. The laminate film includes a base film and a resin matte layer which is laminated on at least one side of the base film. The resin matte layer contains powders fine enough to provide the layer with translucency. At least a surface of the laminate film is processed to have a roughened portion.

Other aspects and advantages of the invention will become apparent from the following description, taken in conjunction with the accompanying drawings, illustrating by way of example the principles of the invention.

### BRIEF DESCRIPTION OF THE SEVERAL VIEWS OF THE DRAWINGS

The invention, together with objects and advantages thereof, may best be understood by reference to the following description of the presently preferred embodiments together with the accompanying drawings in which:

FIG. 1 is a perspective view of a film-integrated key sheet;

FIG. 2 is a cross-sectional view of the first embodiment of the film-integrated key top of the present invention;

FIG. 3 is a cross-sectional view of the second embodiment of the film-integrated key top of the present invention;

FIG. 4 is a cross-sectional view of the third embodiment of the film-integrated key top of the present invention;

FIG. 5 is a cross-sectional view of the third embodiment of the film-integrated key top of the present invention; and

FIG. 6 is a cross-sectional view illustrating a protective film laminated on the surface of the resin film.

### DETAILED DESCRIPTION OF THE PREFERRED EMBODIMENTS

Embodiments of the present invention are now described in detail with reference to the drawings.

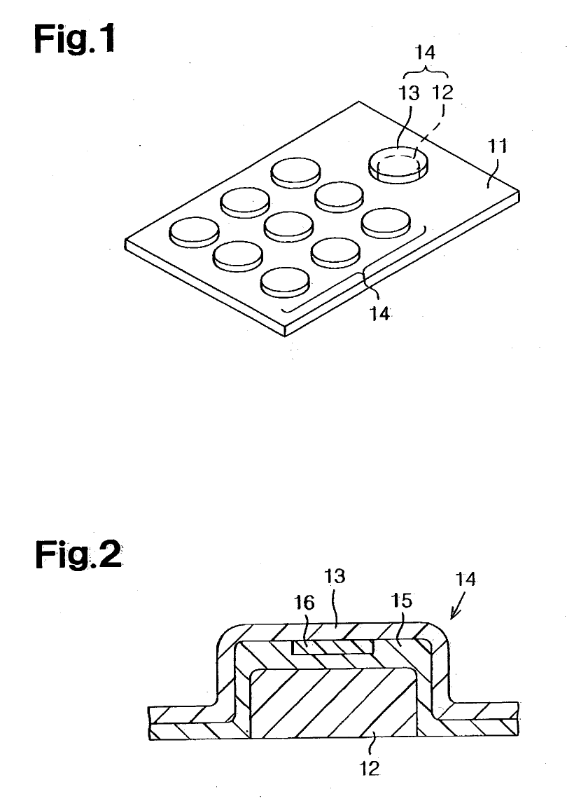

As shown in FIG. 1, a film-integrated key sheet 11 is provided on the surface of mobile device or communication device such as a cellular phone. A plurality of the key tops 12, or push buttons, are located on the key sheet 11. The plurality of resin key tops 12 and a resin film 13 are extended from the key sheet 11. Each resin key top 12 is covered with the resin film 13 and integrated with the resin film 13 to form a film-integrated key top 14. Each film-integrated key top 14 is provided in given size and given position for intended use.

As shown in FIG. 2, a decorative layer 15 is formed on the surface (an upper surface and a side surface in FIG. 1) of each resin key top 12 to cover the entire outer surface of the key top 12. A display portion 16 is provided in the center of the upper surface of the decorative layer 15. The decorative layer 15 and the display portion 16 may be formed by printing. The resin film 13 is provided to cover the decorative layer 15 and the display portion 16. The film-integrated key top 14 is integrally formed, that is, the surface of the resin key top 12 is covered with the resin film 13 which conforms to the surface of the resin key top 12 with the decorative layer 15 and the display portion 16 placed therebeween. The method of manufacturing the film-integrated key top 14 is described in detail below.

Each resin key top 12 is formed into a defined protruding shape by molding synthetic resin such as thermoplastic resin, for example, by injection molding. The synthetic resin includes polycarbonate resin, polyester resin, fluororesin, acrylic resin, acrylonitrile-butadiene-styrene copolymer resin, acrylonitrile-styrene copolymer resin, and acrylonitrile-chlorinated polyethylene-styrene copolymer resin. Among them, polycarbonate resin is preferred in terms of rigidity, translucency, heat resistance, and costs.

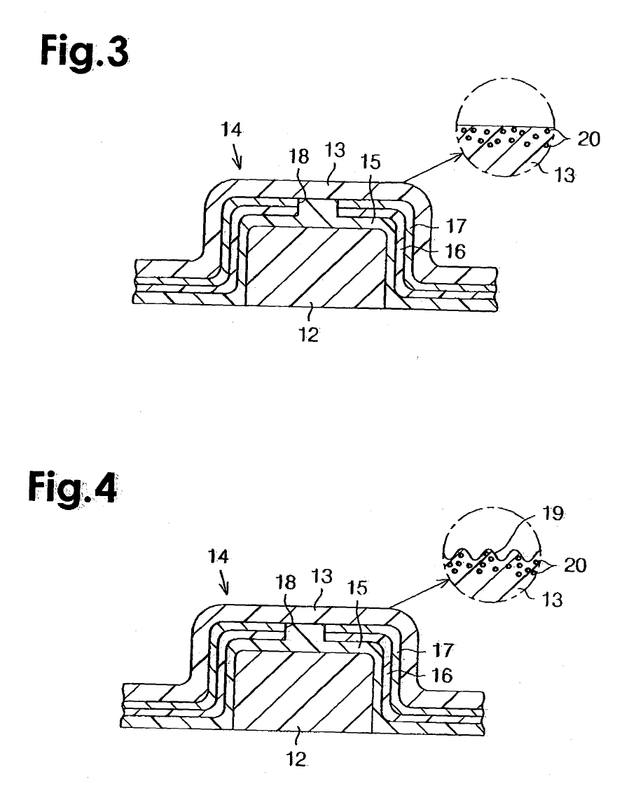

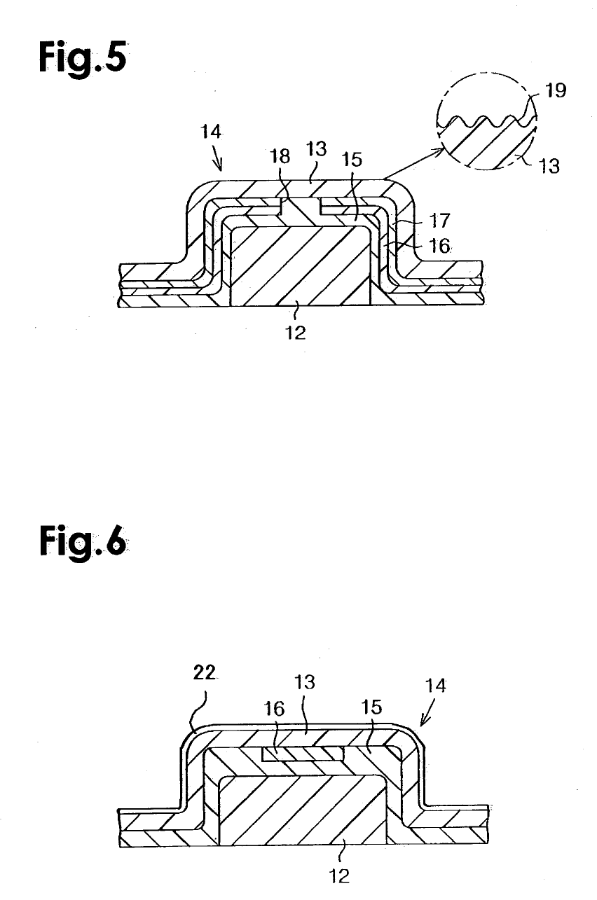

The resin film 13 is formed of synthetic resin such as thermoplastic resin. The resin film 13 is classified in three types. Specifically, in the first embodiment of FIG. 2, the resin film 13 is a matte film which contains powders fine enough to provide the film with translucency. In the second embodiment of FIG. 3, the resin film 13 is a laminate film where a matte layer which contains powders fine enough to provide the film with translucency is laminated on at least one side of the base film. In the third embodiment of FIGS. 4 and 5, the resin film 13 is a processed film in which at least a surface of the base film or the laminate film is processed to have a roughened portion. As used herein, the term “fine enough to provide the film (or the layer) with translucency” means that the surface of the film contains the average particle size of the powders of 40 μm or less, as discussed below.

The fine powders include inorganic powders made of materials such as silica, alumina, calcium carbonate, titanium oxide; and synthetic resin powders made of materials such as acrylic resin, urethane resin, nylon resin, and silicone resin. The amount of the powders is adjusted depending on the required matte texture of the matte film. The amount of the powders is preferably from 0.1 to 50% by weight. If the amount is less than 0.1% by weight, the matte texture of the matte film may be impaired. If the amount is more than 50% by weight, translucency of the matte film may be decreased. The average particle size of the powders in the matte film is preferably 40 μm or less, more preferably 10 μm or less to achieve uniform matte texture and translucency.

A laminating process to laminate the matte layer on the base film includes (a) a extrusion laminating process in which a melt base resin is extruded through the small slit in a T-shaped die of the extruder, the resultant extruded film is laminated on the separate matte layer, and the laminate film is cooled and hardened, (b) a multi-layer molding process in which a melt resin is extruded from each passage of the multi-layer die which has several separate passages in its inside or at the outlet to form a laminate film of the base film and the matte layer, (c) a dry laminate process in which an adhesive dissolved in the solvent is applied to the base film, the solvent is dried, and the base film is pressed against and adhered to matte layer to laminate, (d) a laminate coating process in which a resin coating containing the above-mentioned powders is applied at least one side of the base film to laminate.

To roughen the surface to produce the processed film, methods such as (i) sandblast in which sand is blasted to the base film surface,(ii) etch-matting in which the base film surface is matted by etching with alkali saponified liquid or organic solvent, (iii) a surface coating process in which a resin containing the above-mentioned powders coated on the base film surface, (iv) a method of matting during or after the manufacture process of the base film or the laminate film with an embossing roll; a drum or an endless belt having a rough surface or a matting surface; or a press die.

The roughening process may be applied on the front surface of the base film or the laminate film, the back surface of the base film or the laminate film, or the front and back surfaces of the base film or the laminate film.

Also, the roughening process may be grain finishing the surface by using an injection-molding die which includes surfaces which define a cavity for holding the key top and which have irregular portions when the film-integrated key top is injection-molded.

Among the above-mentioned methods, a laminate coating process, sandblast, etch-matting, a surface coating process, and a method of matting by using a drum or a die can selectively matte the film at the desired location. Thus, selected one(s) of a plurality of key tops may have translucency and matte texture or one key top may have both a matte portion and a luster portion.

The resin which forms the matte layer is generally synthetic resin by not particularly limited if it is adhesive to the base film. As such, the synthetic resin such as urethane resin, acrylic resin, silicone resin, epoxy resin, and ester resin are included. The hardening form of the resin includes thermal hardening, photo-curing, and moisture hardening. Particularly, urethane resin is preferably hardened by thermal hardening.

To provide the key top surface with soft touch or feeling, the resin is preferably thermoplastic elastomer. The thermoplastic elastomer includes polyurethane elastomer, polyolefin elastomer, polyester elastomer, styrene elastomer, and polyvinylchloride elastomer. The hardness of the thermoplastic elastomer is preferably 30 to 98 degree with a Type-A durometer pursuant to JIS K6253.

The composition, elasticity, type and color of the base film are not particularly limited. For example, the base film includes polyester film, polyolefin film, vinyl resin film, fluororesin film, polycarbonate film, polyacetate film, polyamide film, ionomer film, and polyimide film. The film of high transparency is desirable. For such film, fluororesin film, polyester film, polycarbonate film are included.

The resin films 13 of the first to third embodiments preferably have thickness of 12 to 300 μm. When the thickness is less than 12 μm, rigidity of the resin film 13 may decrease and the powders may come out of the surface of the resin film 13. When the thickness is more than 300 μm, translucency or matte texture may be impaired.

Also, the resin films 13 of the first to third embodiments preferably have degree of brilliancy of 1 to 80%, haze value (which indicates degree of haze of the film, greater value means as the film is more clear) of 20 to 70%, and transmittance (transmittance of parallel lights) of 40 to 70% to exhibit both translucency and matte texture. If degree of brilliancy is lower than 1%, the surface may be too rough to achieve excellent matte texture. If degree of brilliancy is higher than 80%, the surface may be optically too smooth to have sufficient matte texture. If haze value is lower than 20%, the film may be too clear to have sufficient matte texture. If haze value is higher than 70%, the film may be too opaque to have excellent matte texture. If transmittance is lower than 40%, the translucency of the lights in the film may be poor. If transmittance is higher than 70%, matte texture of the film may be poor.

In FIGS. 3 and 4, a laminate film is used as the resin film 13. At the back surface of the resin film 13, a metal film 17, a display portion 16, and a decorative layer 15 are provided in order. Each of the metal film 17 and the display portion 16 has a hole 18 above the center of each resin key top 12. The decorative layer 15 extends in the hole 18. The metal film 17 exhibits metallic luster. The metal film 17 is formed by deposition of metal such as aluminum. The display portion 16 and the decorative layer 15 are formed by printing or painting with an ink such as a polyester ink. The display portion 16 may include a character such as a letter and a symbol. The decorative layer 15 may include a graphic. The display portion 16 may include a raised character or a dented character formed by boring a hole. The thickness of the display portion 16 and the decorative layer 15 may be determined depending on their purposes. The thickness of the metal film 17 is preferably from 10 to 60 nm.

In FIG. 3, the resin film 13 contains the powders 20 and the resin film 13 has a flat surface. In FIG. 4, the resin film 13 contains the powders 20 and the resin film 13 has a surface which includes a roughened portion 19 formed by, for example, sandblast.

In FIG. 5, the resin film 13 has a surface which includes a roughened portion 19 formed, for example, by sandblast. Since the roughened portion 19 is formed directly on the surface of the resin film 13, separate beads are eliminated. Thus, the manufacture of the resin film 13 is simplified.

A process of manufacturing the film-integrated key top 14, where the resin film 13 is integrally formed on the surface of the resin key top 12, is generally conducted as follows.

Synthetic resin such as polyethylene terephthalate that contains powders such as silica powders is used as a raw material of the resin film 13. The synthetic resin is extruded by extrusion molding and stretched by biaxial stretching to form a stretched resin film 13. Then, the resin film 13 is cut out to the size suitable for manufacturing each resin key top 12. If required, the display portion 16 or the decorative layer 15 may be formed at the back surface of the resin film 13 by printing or painting. Further, the metal film 17 may be formed at the back surface of the resin film 13 by deposition of metal such as aluminum.

The resin film 13 is deformed in the shaping die to conform to the surface of each resin key top 12. The deformed resin film 13 is inserted in the cavity of the die for injection molding of each resin key top 12. Then, thermoplastic resin such as polycarbonate resin, which is thermoplastic resin and a material of each resin key top 12, is injected in the same cavity to integrate the resin film 13 with each resin key top 12. Finally, the perimeter of the integrated resin key tops 12 is cut out by punching.

Thus, a film-integrated key top 14, in which the resin key top 12 and the resin film 13 that conforms to the surface of the resin key top 12 are integrally formed, are produced.

The resin film 13 of the resultant film-integrated key top 14 may be formed of the matte film or matte layer that contains powders fine enough to provide the film with translucency or the base film or the laminate film that has a surface which includes a roughened portion 19. Therefore, the resin film 13 can transmit lights and the transmit lights are refracted or reflected diffusely by the fine powders or the roughened portion. This causes the surface of the resin film 13 to have a matte appearance.

As shown in FIG. 6, a detachable protective film 22 may be laminated on the surface of the resin film 13 of any one of first to third embodiments. The protective film 22 can protect the surface of the film-integrated key top 14 prior to its use. The protective film 22 may be detached when the film-integrated key top 14 is used.

Further, when the protective film 22 is used with the resin film 13 of the third embodiment, the surface of the protective film 22 may have a roughened portion such that the portion is transferred to the resin film 13. In this case, the roughened portion 19 of the surface the resin film 13 is easily produced.

The protective film 22 may also be used to prevent blocking and deformation or damage of a thermoplastic elastomer when the thermoplastic elastomer, which serves as a laminate film and has a heat resistance lower than a base film, is contacted with a heat roller. Further, the protective film 22 may be used to prevent the thermoplastic elastomer from fusing to the heat roller and then to prevent the thermoplastic elastomer from fusing to the mold.

The roughened portion of the protective film 22 may be made by coating the surface of the protective film 22 with melamine resin containing silica powders or mixing powders in the protective film 22. The protective film 22 is preferably made from a material which is hard to adhere to thermoplastic elastomer or, in the case thermo-laminating process is used, a material which is blocking-free with the heat roller. When the thermoplastic elastomer is thermoplastic polyurethane elastomer, such material is, for example, oriented polypropylene and polyethylene terephthalate or polycarbonate the surface of which is treated with melamine resin to detach from the mold. Preferably, the protective film 22 has a thickness of 25 μm or less, more preferably 6 to 25 μm, most preferably 12 μm. When the thickness is larger than 25 μm, transmission of heat is insufficient during the thermo-laminating process, which results in insufficient adhesive strength between the base film and the thermoplastic elastomer film.

The advantages of the above-mentioned embodiments are described below.

The resin film 13 is formed of a matte film that contains powders fine enough to provide the film with translucency. Accordingly, the film-integrated key top 14 can show excellent translucency as well as excellent matte texture. In addition, when the average particle size of the powders is less than 40 μm and the powder is dispersed uniformly in the matte film, more excellent translucency and uniform matte texture can be achieved.

The resin film 13 is formed of a laminate film where a matte layer which contains powders fine enough to provide the film with translucency is laminated on at least one side of the base film. Accordingly, the film-integrated key top 14 can show excellent translucency as well as excellent matte texture.

The resin film 13 is formed of a processed film. The processed film is either a base film which has translucency and which is processed to have a roughened portion 19 or a laminate film where a matte layer which contains powders fine enough to provide the film with translucency is laminated on at least one side of the base film and which is processed to have a roughened portion 19. Accordingly, the film-integrated key top 14 can show excellent translucency as well as excellent matte texture.

The film-integrated key top 14, which has excellent translucency as well as excellent matte texture, has an aesthetic taste. The key top 14 can be easily manufactured by using the resin film 13 and the manufacturing costs can be reduced. Further, by adjusting the average particle size or the amount of the powders in the matte film or the matte layer of the laminate film, or the thickness of the matte film or layer which contains the powders, the matte texture can be controlled freely.

### EXAMPLES

The above-mentioned embodiments are described in more detail in connection with examples and a comparative example. All the materials used in each example, such as resin, film, and ink, are only illustrative and non-limiting.

### Example 1

This example is for a film-integrated key top 14 of FIG. 2.

Polyethylene terephthalate containing silica powders (average particle size of 1 to 2 μm) as fine powders was stretched by biaxial stretching to form a sheet of a resin film 13 having a thickness of 50 μm. Dust or other foreign particles were removed from the surface of the resin film 13. This matte film was cut to an appropriate size. A display portion 16 was formed at the back surface of the film 13 by printing with a polyester ink. The display portion 16 included a raised character. Further, a decorative layer 15 was formed by solid printing with a polyester ink.

The film 13 was deformed in the shaping die to conform to the surface of each resin key top 12. The deformed film 13 was inserted in the die for injection molding of the resin key top 12. Then, polycarbonate resin, which is thermoplastic resin and a material of the resin key top 12, is injection-molded to integrate the resin film 13 with each resin key top 12. Finally, the perimeter of the integrated key tops was cut out by punching to produce film-integrated key tops 14 each of which includes a surface having uniform matte texture and includes the display portion 16 having a raised character.

### Example 2

This example is for a film-integrated key top 14 of FIG. 3.

Polyethylene terephthalate was stretched by biaxial stretching to form a sheet of a base film having a thickness of 50 μm. Dust or other foreign particles were removed from the surface of the base film. Then, by the surface coating process, urethane resin containing silica powders (average particle size of 1 to 2 μm) as fine powders was applied to the surface of the base film with a roll coater to produce a laminate film. The thickness of the applied urethane resin was 2 to 5 μm. The coating was carefully conducted so as not to make a scratch on the surface of the film.

The deposition of aluminum was performed by using a batch take-up deposition machine to form a metal film 17 at the back surface of the resin film 13. The metal film 17 had a thickness of 40 nm.

The resin film 13 was cut to an appropriate size. A display portion 16 was formed at the back surface of the film 13 by printing with a polyester ink. The display portion 16 included a dented character. At the proximate of the dented character, the metal film 17 was alkali-etched to remove an exposed part. The alkali-etching was conducted according to a known technique. The film was neutralized, washed intensively, dried, and printed with a polyester ink to form a decorative layer 15.

The film 13 was deformed in the shaping die to conform to the surface of each resin key top 12. The deformed film 13 was inserted in the die for injection molding of the resin key top 12. Then, polycarbonate resin, which is thermoplastic resin and a material of the resin key top 12, is injection-molded to integrate the resin film 13 with each resin key top 12. Finally, the perimeter of the integrated key tops was cut out by punching to produce film-integrated key tops 14 each of which includes a surface having uniform matte texture and includes the display portion 16 having a dented character.

### Example 3

This example is for a film-integrated key top 14 of FIG. 4.

Polyethylene terephthalate film was coextruded with polyethylene terephthalate film containing fine powders to form a resin film 13 with the polyethylene terephthalate film containing fine powders placed on both (front and back) sides of the polyethylene terephthalate base film. Concurrently with the laminating, minute roughened portion was made on the film by using an embossing roll. Each of the polyester layers had a thickness of 5 μm. The total thickness of the laminate film was 50 μm.

The deposition of aluminum was performed by using a batch take-up deposition machine to form a metal film 17 at the back surface of the resin film 13. The deposition of aluminum was performed by using a batch take-up deposition machine to form a metal film 17 at the back surface of the resin film 13.

The resin film 13 was cut to an appropriate size. A display portion 16 was formed at the back surface of the film 13 by printing with a polyester ink. The display portion 16 included a dented character. At the proximate of the dented character, the metal film 17 was alkali-etched to remove an exposed part. The alkali-etching was conducted according to a known technique. The film was neutralized, washed intensively, dried, and printed with a polyester ink to form a decorative layer 15.

The film 13 was deformed in the shaping die to conform to the surface of each resin key top 12. The deformed film 13 was inserted in the die for injection molding of the resin key top 12. Then, polycarbonate resin, which is thermoplastic resin and a material of the resin key top 12, is injection-molded to integrate the resin film 13 with each resin key top 12. Finally, the perimeter of the integrated key tops was cut out by punching to produce film-integrated key tops 14 each of which includes a surface having uniform matte texture and includes the display portion 16 having a dented character.

### Example 4

This example was prepared in the same manner as Example 3, except that the following laminate film was used as a resin film 13.

A laminate film was formed by an extrusion laminating process in which polyethylene terephthalate film containing fine powders was laminated on both sides of polyethylene terephthalate film as a base film and extruded into a sheet. Each of the polyester layers in the laminate film had a thickness of 5 μm. The total thickness of the laminate film was 50 μm. A resultant film-integrated key top 14 included a surface having uniform matte texture.

### Example 5

This example was prepared in the same manner as Example 3, except that the following laminate film was used as a resin film 13.

A laminate film was formed by a dry laminate process in which acrylic adhesive was applied to polyethylene terephthalate film, pressed against and adhered to a polyester layer containing silica powders (average particle size of 1 to 2 μm) as fine powders to laminate. A resultant film-integrated key top 14 included a surface having uniform matte texture.

### Example 6

This example is for a film-integrated key top 14 of FIG. 5.

This example was prepared in the same manner as Example 3, except that the resin film 13 was a processed film which was formed by sandblast in which a polyethylene terephthalate film was roughened by being blasted sand. A resultant film-integrated key top 14 included a surface having uniform matte texture.

### Example 7

This example was prepared in the same manner as Example 3, except that the resin film 13 was a processed film which was formed by etch-matting in which the surface of a polyethylene terephthalate film was etched with alkali saponified liquid to have a roughed portion. A resultant film-integrated key top 14 included a surface having uniform matte texture.

### Example 8

This example was prepared in the same manner as Example 3, except that the resin film 13 was a processed film which was formed by matting the surface of the polyethylene terephthalate film during the manufacture with an embossing roll. A resultant film-integrated key top 14 included a surface having uniform matte texture.

### Example 9

This example was prepared in the same manner as Example 3, except that the resin film 13 was a processed film which was formed by matting the surface of the polyethylene terephthalate film with a press die. A resultant film-integrated key top 14 included a surface having uniform matte texture.

### Example 10

Polyethylene terephthalate film was stretched by biaxial stretching to form a sheet of a resin film 13 having a thickness of 50 μm. A display portion 16 was formed at the back surface of the film 13 by printing with a polyester ink. The display portion 16 included a dented character. The film 13 was deformed in the shaping die to conform to the surface of the resin key top 12. The resin film 13 was then inserted in a injection-molding die which includes surfaces which define a cavity for holding the key top and the surfaces have grain-finished portions. Polycarbonate resin, which is thermoplastic resin and a material of the resin key top 12, was injection-molded to integrate the resin film 13 with each resin key top 12. Finally, the perimeter of the integrated resin key top 12 is cut out by punching to produce film-integrated key tops 14 each of which includes a surface having uniform matte texture and includes the display portion 16 having a dented character.

Degree of brilliancy (%), haze value (%), and transmittance of parallel lights (%) of the resin film of Examples 2 to 4 and 6 and those of general polyethylene terephthalate (PET) film (Comparative example) were measured pursuant to JIS K7105. The results are shown in Table 1.

TABLE 1

| | | | | | PET |
|---|---|---|---|---|---|
| | Example 2 | Example 3 | Example 4 | Example 6 | film |
| Degree of | 39 | 40 | 76 | 6 | 150 |
| brilliancy(%) | | | | | |
| haze value(%) | 35 | 33 | 59 | 26 | 4 |
| transmittance(%) | 66 | 57 | 45 | 53 | 85 |

As shown in Table 1, degrees of brilliancy of the resin films of Examples 2 to 4 and 6 are much lower than that of the general PET film, indicating that the films of Examples 2 to 4 and 6 are matte. The haze values of the resin films of Examples 2 to 4 and 6 are much higher than that of the general PET film, indicating that the films of Examples 2 to 4 and 6 are in a haze. The transmittances of the resin films of Examples 2 to 4 and 6 are lower than that of the general PET film, indicating that the films of Examples 2 to 4 and 6 transmit smaller amount of lights.

### Example 11

This example is for a film-integrated key top 14 of FIG. 3.

A matte layer, which is a thermoplastic elastomer film containing slilica powders (average particle size of 1 to 2 μm) as fine powders, was laminated on the surface of the base film, which is an alloy film of polycarbonate and polybutylene terephthalate (an PC/PBT film), by thermo-laminating method to form a laminate film. The thermoplastic elastomer film was formed by extruding polyurethane elastomer through the small slit in a T-shaped die of the extruder to have a thickness of 50 μm.

Dust or other foreign particles were removed from the back surface of the resin film 13. This laminate film was cut to an appropriate size. A display portion 16 was formed at the back surface of the film 13 by printing with a polyester ink. The display portion 16 included a raised character. Further, decorative layer 15 was formed by solid printing with a polyester ink.

The laminate film was deformed in the shaping die to conform to the surface of each resin key top 12. The deformed film was inserted in the die for injection molding of each resin key top 12. Then, polycarbonate resin, which is thermoplastic resin and a material of the resin key top 12, is injection-molded to integrate the resin film 13 with each resin key top 12. Finally, the perimeter of the integrated key tops was cut out by punching to produce film-integrated key tops 14 each of which includes a surface having a soft touch and includes the display portion 16 having a raised character.

### Example 12

This example is for a film-integrated key top 14 of FIG. 4.

A thermoplastic elastomer film having a thickness of 50 μm and a protective film having a roughened portion on the laminating surface were laminated on the surface of the base film. By thermo-laminating method to form a laminate film which has a protective film on its surface, the base film is a polyethylene terephthalate film having a thickness of 50 μm. The thermoplastic elastomer film was formed by extruding polyurethane elastomer through the small slit in a T-shaped die of the extruder.

Dust or other foreign particles were removed from the surface of the processed film. Further, the deposition of aluminum was performed by using a batch take-up deposition machine to form a metal film 17 at the back surface of the processed film. The metal film 17 had a thickness of 40 nm.

This matte film was cut to an appropriate size. A display portion 16 was formed at the back surface of the film 13 by printing with a polyester ink. The display portion 16 included a dented character. At the proximate of the dented character, the metal film 17 was alkali-etched to remove an exposed part. The alkali-etching was conducted according to a known technique in the art. The film was neutralized, washed intensively, dried, and printed with a polyester ink to form a decorative layer 15.

The processed film was deformed in the shaping die to conform to the surface of the resin key top 12. The deformed film was inserted in the die for injection molding of each resin key top 12. Then, polycarbonate resin, which is thermoplastic resin and a material of the resin key top 12, is injection-molded to integrate the resin film 13 with each resin key top 12. Finally, the perimeter of the integrated key tops was cut out by punching. The protective film was detached and a roughened portion on the protective film were transferred. Thus, a film-integrated key top 14 that includes a surface having soft touch and includes the display portion 16 having a dented character was produced.

### Example 13

This example is for a film-integrated key top 14 of FIG. 5.

A matte layer, which is a thermoplastic elastomer film containing silica powders (average particle size of 1 to 2 μm) as fine powders, and a protective film, which has a roughened portion on the laminating surface, were laminated on the surface of the base film, which is an PC/PBT film, by thermo-laminating method to form a laminate film which has a protective film on its surface. The thermoplastic elastomer film was formed by extruding polyurethane elastomer through the small slit in a T-shaped die of the extruder to have a thickness of 50 μm. The resultant laminate film was used to produce a film-integrated key top 14, as described in Example 3. The film-integrated key top 14 included a surface having soft touch.

Degree of brilliancy (%), haze value (%), and transmittance of parallel lights (%) of the resin film of Examples 11 to 13 were measured in the same way as in Examples 2 to 4 and 6. The results are shown in Table 2.

TABLE 2

| | Example 11 | Example 12 | Example 13 |
|---|---|---|---|
| Degree of | 67 | 50 | 64 |
| brilliancy(%) | | | |
| haze value(%) | 51 | 32 | 55 |
| transmittance(%) | 62 | 64 | 59 |

As shown in Table 2, degrees of brilliancy of the resin films of Examples 11 to 13 are much lower than that of the general PET film, indicating that the films of Examples 2 to 4 and 6 are matte. The haze values of the resin films of Examples 11 to 13 are much higher than that of the general PET film, indicating that the films of Examples 2 to 4 and 6 are in a haze. The transmittances of the resin films of Examples 11 to 13 are lower than that of the general PET film, indicating that the films of Examples 2 to 4 and 6 transmit smaller amount of lights.

It should be apparent to those skilled in the art that the present invention may be embodied in many other specific forms without departing from the spirit or scope of the invention. Particularly, it should be understood that the invention may be embodied in the following forms.

An adhesive or an agglutinant may be used when the resin key top 12 and the resin film 13 are integrally formed.

In a laminate film of the base film and the matte layer, a plurality of the matte layers can be used. The amount and kind of the powders contained in each matte layer can be varied.

A roughened portion 19 may not include protrusions and depressions alternately. For example, shape of the cross-section of the protrusions and the depressions may be varied. The height of the protrusions and the depth of the depressions may be varied. In addition, density of the protrusions and the depressions may be varied.

The display portion 16 and the decorative layer 15 may be formed at the back surface of the resin film 13 by applying a paint, instead of printing.

Therefore, the present examples and embodiments are to be considered as illustrative and not restrictive and the invention is not to be limited to the details given herein, but may be modified within the scope and equivalence of the appended claims.

1. A film-integrated key top comprising:
a resin key top; and
a resin film integrated with the resin key top, wherein the resin film includes a matte film that contains powders fine enough to provide the film with translucency.

2. A film-integrated key top comprising:
a resin key top; and
a resin film integrated with the resin key top, wherein the resin film include a laminate film, wherein the laminate film includes a base film and a resin matte layer which is laminated on at least one side of the base film, wherein the resin matte layer contains powders fine enough to provide the layer with translucency.

3. A film-integrated key top comprising;
a resin key top; and
a resin film integrated with the resin key top, wherein the resin film includes a base film which has translucency, wherein at least a surface of the base film is processed to have a roughened portion.

4. A film-integrated key top comprising;
a resin key top; and
a resin film integrated with the resin key top, wherein the resin film includes a laminate film, wherein the laminate film includes a base film and a resin matte layer which is laminated on at least one side of the base film, wherein the resin matte layer contains powders fine enough to provide the layer with translucency, wherein at least a surface of the laminate film is processed to have a roughened portion.

5. A film-integrated key top according to claim 1, wherein the powders have an average particle size of 40 μm or less.

6. A film-integrated key top according to claim 2, wherein the powders have an average particle size of 40 μm or less.

7. A film-integrated key top according to claim 4, wherein the powders have an average particle size of 40 μm or less.

8. A film-integrated key top according to claim 1, further comprising at least one selected from the group consisting of a decorative layer, a display portion, and a metal film, wherein the selected one is located between the resin key top and the resin film.

9. A film-integrated key top according to claim 2, further comprising at least one selected from the group consisting of a decorative layer, a display portion, and a metal film, wherein the selected one is located between the resin key top and the resin film.

10. A film-integrated key top according to claim 3, further comprising at least one selected from the group consisting of a decorative layer, a display portion, and a metal film, wherein the selected one is located between the resin key top and the resin film.

11. A film-integrated key top according to claim 4, further comprising at least one selected from the group consisting of a decorative layer, a display portion, and a metal film, wherein the selected one is located between the resin key top and the resin film.

12. A film-integrated key top according to claim 1, wherein the resin film has a thickness from 12 to 300 μm.

13. A film-integrated key top according to claim 2, wherein the resin film has a thickness from 12 to 300 μm.

14. A film-integrated key top according to claim 3, wherein the resin film has a thickness from 12 to 300 μm.

15. A film-integrated key top according to claim 4, wherein the resin film has a thickness from 12 to 300 μm.

16. A film-integrated key top according to claim 1, wherein the resin film has degree of brilliancy of 1 to 80%, haze value of 20 to 70%, and transmittance of 40 to 70%.

17. A film-integrated key top according to claim 2, wherein the resin film has degree of brilliancy of 1 to 80%, haze value of 20 to 70%, and transmittance of 40 to 70%.

18. A film-integrated key top according to claim 3, wherein the resin film has degree of brilliancy of 1 to 80%, haze value of 20 to 70%, and transmittance of 40 to 70%.

19. A film-integrated key top according to claim 4, wherein the resin film has degree of brilliancy of 1 to 80%, haze value of 20 to 70%, and transmittance of 40 to 70%.

20. A film-integrated key top according to claim 2, wherein the resin matte layer is formed of thermoplastic elastomer.

21. A film-integrated key top according to claim 4, wherein the resin matte layer is formed of thermoplastic elastomer.
